(19) United States
(12) Patent Application Publication
(10) Pub. No.: US 2026/0100330 A1
(43) Pub. Date: Apr. 9, 2026

(54) IGNITION FOR INDUCTIVELY COUPLED PLASMA

(71) Applicant: ASM IP Holding B.V., Almere (NL)

(72) Inventors: Ronald Anthony Decker, Turnersville, NJ (US); Imran Ahmed Bhutta, Moorestown, NJ (US)

(21) Appl. No.: 19/347,926

(22) Filed: Oct. 2, 2025

Related U.S. Application Data
(60) Provisional application No. 63/704,258, filed on Oct. 7, 2024.

(51) Int. Cl. H01J 37/32

(52) U.S. Cl. CPC H01J 37/3211

(57) ABSTRACT

In one embodiment, the present disclosure is directed to a system for generating inductively-coupled plasma. The system includes a dielectric tube and an inductive coil circuit. The inductive coil circuit includes inductive coils surrounding the dielectric tube and connected in series to each other. Intervening capacitors are switchably coupled between the inductive coils. A control circuit is configured to, upon determining a plasma will be ignited, cause at least one of the intervening capacitors to be switched out of the inductive coil circuit during ignition of the plasma.

### CROSS-REFERENCE TO RELATED APPLICATIONS

This application claims priority to U.S. Provisional Patent Application Ser. No. 63/704,258 filed Oct. 7, 2024 and titled IMPROVED IGNITION FOR INDUCTIVELY COUPLED PLASMA, the disclosure of which is hereby incorporated by reference in its entirety.

### BACKGROUND

Substrate processing systems can use inductively-coupled plasma (ICP) for processing a substrate. The processes run by the system can be short and therefore require fast and reliable ignition of the plasma. They may also require the ICP source to ignite process gasses under various chemistry and pressure conditions. Such requirements present various challenges. For example, in high power applications, sustained high voltage across the ICP coil may cause heating of the dielectric tube due to ion bombardment. But a high voltage is needed to ignite the plasma in ICP applications.

### BRIEF SUMMARY

The present disclosure discusses a system and method for preventing over-heating of the dielectric tube while ensuring sufficient voltage to reliably ignite the inductively-coupled plasma.

The present disclosure may be directed, in one aspect, to a system comprising a dielectric tube; an inductive coil circuit comprising inductive coils surrounding the dielectric tube and connected in series to each other; intervening capacitors coupled between the inductive coils, each intervening capacitor comprising either one fixed capacitor or a plurality of fixed capacitors coupled in parallel; and switches operably coupled to the intervening capacitors; and a control circuit configured to, upon determining a plasma will be ignited, cause at least one of the switches to switch at least one of the fixed capacitors of the intervening capacitors out of the inductive coil circuit during ignition of the plasma.

In another aspect, a method of improving ignition of plasma comprises surrounding a dielectric tube with inductive coils of an inductive coil circuit, the inductive coil circuit comprising the inductive coils connected in series to each other; intervening capacitors coupled between the inductive coils, each intervening capacitor comprising one or more fixed capacitors coupled in parallel; and switches operably coupled to the intervening capacitors; and upon determining a plasma will be ignited, causing at least one of the switches to switch at least one of the fixed capacitors of the intervening capacitors out of the inductive coil circuit during ignition of the plasma.

### BRIEF DESCRIPTION OF THE DRAWINGS

The present disclosure will become more fully understood from the detailed description and the accompanying drawings, wherein:

FIG. 1 is a block diagram of a system for processing substrates according to one embodiment.

FIG. 2 is a block diagram of inductively-coupled plasma source according to one embodiment.

FIG. 3 is a schematic diagram of a first inductive coil circuit according to a first embodiment.

FIG. 4 is a schematic diagram of a portion of a second inductive coil circuit according to a second embodiment.

FIG. 5 is a schematic diagram of a portion of a third inductive coil circuit according to a third embodiment.

FIGS. 6A-C are schematic diagrams of switches according to different embodiments.

FIG. 7 is a flow chart of a method for improving ignition of a plasma according to one embodiment.

The drawings represent one or more embodiments of the present invention(s) and do not limit the scope of invention.

### DETAILED DESCRIPTION

The following description of the preferred embodiment(s) is merely exemplary in nature and is in no way intended to limit the invention or inventions. The description of illustrative embodiments is intended to be read in connection with the accompanying drawings, which are to be considered part of the entire written description. The discussion herein describes and illustrates some possible non-limiting combinations of features that may exist alone or in other combinations of features. Furthermore, as used herein, the term “or” is to be interpreted as a logical operator that results in true whenever one or more of its operands are true. Furthermore, as used herein, the phrase “based on” is to be interpreted as meaning “based at least in part on,” and therefore is not limited to the interpretation “based entirely on. ” Furthermore, the term “each,” when used in reference to each of a plurality of items, need not refer to each such item in an entire system or apparatus, but may instead simply refer to each of the specifically recited items in the system.

As used throughout, ranges are used as shorthand for describing each and every value that is within the range. Any value within the range can be selected as the terminus of the range. In addition, all references cited herein are hereby incorporated by referenced in their entireties. In the event of a conflict in a definition in the present disclosure and that of a cited reference, the present disclosure controls.

In the following description, where block diagrams or circuits are shown and described, one of skill in the art will recognize that, for the sake of clarity, not all peripheral components or circuits are shown in the figures or described in the description. For example, common components such as memory devices and power sources may not be discussed herein, as their role would be easily understood by those of ordinary skill in the art. Further, when two components are said to be “coupled” or “operably coupled,” this includes components that are associated in any way such that power or signal information may be transferred (directly or indirectly) from one to another, and thus these terms do not require a direct connection between the components with no intermediaries.

It is noted that for the sake of clarity and convenience in describing similar components or features, the same or similar reference numbers may be used herein across different embodiments or figures. This is not to imply that the components or features identified by a particular reference number must be identical across different embodiments, but to suggest at a minimum that the components or features are similar in general function or identity.

Features of the present inventions may be implemented in software, hardware, firmware, or combinations thereof. The computer programs described herein are not limited to any particular embodiment, and may be implemented in an operating system, application program, foreground or background processes, driver, or any combination thereof. The computer programs may be executed on a single computer or server processor or multiple computer or server processors.

Processors described herein may be any central processing unit (CPU), microprocessor, micro-controller, computational, or programmable device or circuit configured for executing computer program instructions (e.g., code). Various processors may be embodied in computer and/or server hardware of any suitable type (e.g., desktop, laptop, notebook, tablets, cellular phones, etc.) and may include all the usual ancillary components necessary to form a functional data processing device including without limitation a bus, software and data storage such as volatile and non-volatile memory, input/output devices, graphical user interfaces (GUIs), removable data storage, and wired and/or wireless communication interface devices including Wi-Fi, Bluetooth, LAN, etc. As used herein, the term “processor” may refer to one or more processors.

Computer-executable instructions or programs (e.g., software or code) and data described herein may be programmed into and tangibly embodied in a non-transitory computer-readable medium that is accessible to and retrievable by a respective processor as described herein which configures and directs the processor to perform the desired functions and processes by executing the instructions encoded in the medium. A device embodying a programmable processor configured to such non-transitory computer-executable instructions or programs may be referred to as a “programmable device”, or “device”, and multiple programmable devices in mutual communication may be referred to as a “programmable system.” It should be noted that non-transitory “computer-readable medium” as described herein may include, without limitation, any suitable volatile or non-volatile memory including random access memory (RAM) and various types thereof, read-only memory (ROM) and various types thereof, USB flash memory, and magnetic or optical data storage devices (e.g., internal/external hard disks, floppy discs, magnetic tape CD-ROM, DVD-ROM, optical disk, ZIP™ drive, Blu-ray disk, and others), which may be written to and/or read by a processor operably connected to the medium.

In certain embodiments, the present inventions may be embodied in the form of computer-implemented processes and apparatuses such as processor-based data processing and communication systems or computer systems for practicing those processes. The present inventions may also be embodied in the form of software or computer program code embodied in a non-transitory computer-readable storage medium, which when loaded into and executed by the data processing and communications systems or computer systems, the computer program code segments configure the processor to create specific logic circuits configured for implementing the processes.

As discussed above, in high power applications, sustained high voltage across the ICP coil may cause heating of the dielectric tube due to ion bombardment. To solve this problem, one may, for example, insert capacitors between the inductors of the ICP coil to reduce the voltage. The capacitors counteract the voltage created by the inductive coils, keeping the overall ICP coil voltage low. This is the approach taken in U.S. Pat. No. 10,541,114, which is incorporated herein by reference in its entirety. This approach is effective in preventing heating of the dielectric tube. But a high voltage across the ICP coils is needed to reliably ignite the plasma in ICP applications. Thus, by reducing the voltage, plasma ignition becomes less reliable.

One could attempt to address this low-voltage ignition issue by using, for ignition, a separate, secondary inductive coil structure and a separate generator attached to the ICP coil through which one would inject another frequency. But these components would add significant cost. One could also or alternatively inject a short, high-voltage DC pulse to kick start the plasma, but this approach would similarly require a separate inductive coil structure or separate electrodes on the two sides, and thus would add significant cost.

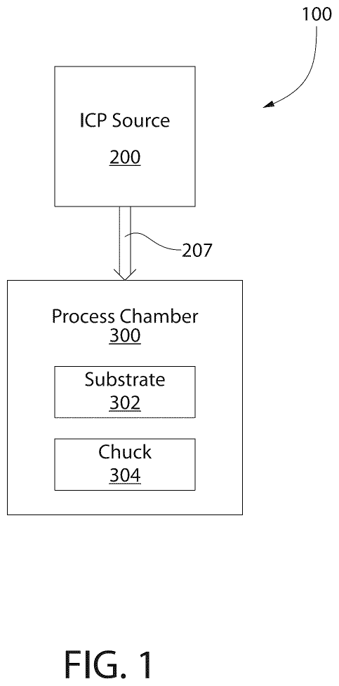

The present disclosure discusses a simpler and more cost-efficient system and method that prevents heating of the dielectric tube while also ensuring sufficient voltage to ignite the plasma. Turning to the figures, FIG. 1 is a block diagram of a system 100 for processing substrates according to one embodiment. The system 100 includes an inductively-coupled plasma (ICP) source (e.g., remote plasma unit) providing ICP 207 to a process chamber 300. The process chamber 300 is shown including standard components such as a chuck 304 for holding a substrate 302. It is noted that process chambers are well known, and thus they are not discussed at length here. For more details about the potential characteristics of a process chamber, see, for example, U.S. Pat. No. 10,541,114 (incorporated by reference).

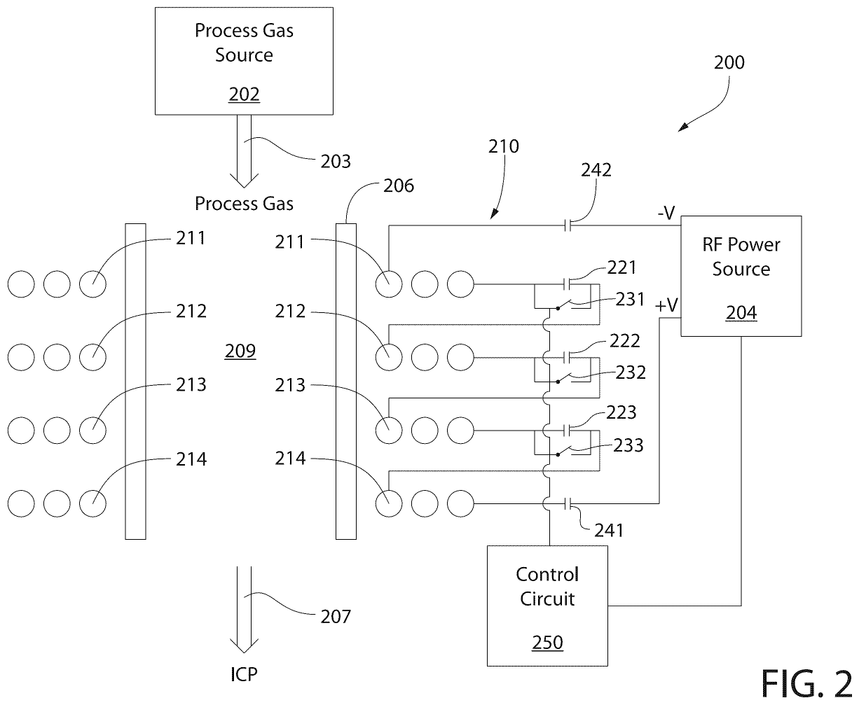

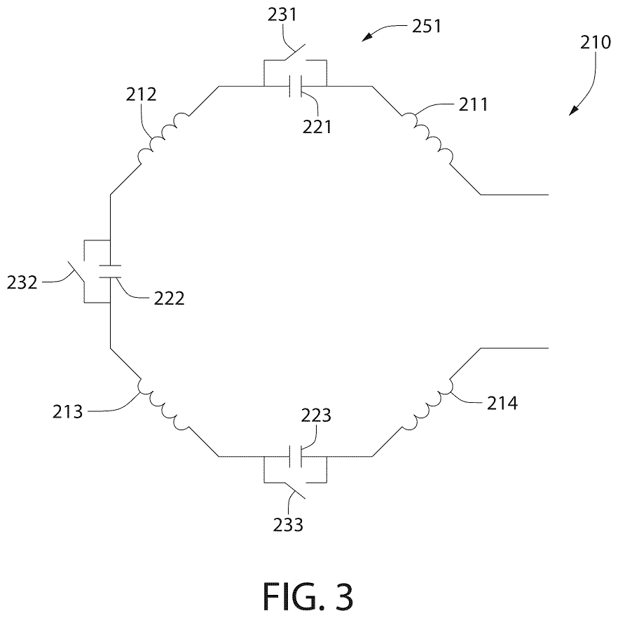

FIG. 2 is a block diagram of the ICP source 200, and FIG. 3 is a schematic diagram of a first inductive coil circuit 210 of the ICP source 200 according to one embodiment. The ICP source 200 is configured to produce inductively-coupled plasma, such as (but not limited to) inductively-coupled hydrogen plasma. The exemplified process gas source 202 provides a process gas 203 to a dielectric tube 206. The dielectric tube 206 is surrounded by inductive coils 211, 212, 213, 214 that form part of an inductive coil circuit 210 that receives radio frequency (RF) power from an RF power source 204. The inductive coils 211-214 are connected in series to each other. Four inductive coils 211-214 are utilized, but the invention is not limited to any particular number of inductive coils. Intervening capacitors 221, 222, 223 are coupled between the inductive coils 211-214, and switches 231-233 are operably coupled to the intervening capacitors 221-223 to enable the intervening capacitors 221-223 to be switched out of the inductive coil circuit 210 (in this example, by being short circuited). In this embodiment, each intervening capacitor 221-223 is respectively coupled between adjacent ones of the inductive coils 211-214 (e.g., intervening capacitor 221 is coupled between adjacent inductive coils 211 and 212), and the intervening capacitors 221-223 are in series with the inductive coils 211-214.

It is noted that, when plasma ignites in an inductively coupled coil, the impedance of the coil changes significantly due, in large part, to the interaction between the plasma and the coil's electromagnetic field. When the plasma ignites, it becomes a conductive medium that interacts with the magnetic field of the coil. The interaction induces currents in the plasma thereby affecting the coil's impedance. The ignited plasma will typically provide a path for the induced currents, reducing the inductive reactance of the coil, causing the coil's impedance to drop when the plasma ignites. After ignition, the impedance will stabilize at a new value that is lower than the initial impedance. The new impedance will depend on factors such as plasma density, temperature, and the frequency of the applied electromagnetic field.

A control circuit 250 is configured to, upon determining a plasma 209 will be ignited, cause at least one the switches 231-233 to switch at least one of the fixed capacitors 221-223 of the intervening capacitors out of the inductive coil circuit 210 during ignition of the plasma 209. The exemplified control circuit 250 is further configured to, after ignition of the plasma, switch the at least one of the fixed capacitors switched out of the inductive coil circuit switched back into the inductive coil circuit, thus enabling the inductive coil circuit 210 to have two modes of operation, one for periods of ignition and one for periods without ignition. By enabling these two modes, the ICP source 200 is able to generate high voltage across the inductive coils 211-214 during ignition to aid ignition, and also bring the capacitors back into the circuit to reduce voltage in the inductive coils and prevent over-heating of the dielectric tube. Developing high voltage across the inductive coils 211-214 raises the resonant frequency of the inductive coils 211-214. The frequency from the RF power source 204 may also be increased to further raise the voltage across the inductive coils 211-214 and the load can become resonant. Once the plasma 209 is ignited and the capacitors 221-223 enter back into the circuit, the resonant frequency of the inductive coils 211-214 will lower, and the frequency from the RF power source 204 may also be decreased. The driving frequency of the RF power source 204 may vary, for example, from hundreds of kilohertz to several megahertz. Its RF power may also vary, for example, from tens of watts to tens of kilowatts.

There are a number of potential methods by which the control circuit 250 can determine that the plasma 209 will be ignited, and thus that at least one of the intervening capacitors 221-223 should be switched out. For example, the control circuit 250 can determine that the RF power from the RF power source 204, which may be provided to the inductive coil circuit 210, is turned OFF or is in the OFF state. In response, the control circuit 250 could automatically switch out the at least one intervening capacitor to prepare for the next ignition. The control circuit 250 could know the RF power is turned OFF based on a signal received from the RF power source 204. For example, a matching network (not shown) coupled to the control circuit could receive an RF ON signal that notifies the match (and thus the control circuit) when the RF power is ON or OFF. Alternatively, the VI sensor or directional coupler could be used to detect the presence of RF power. Ignition may be occurring rapidly (e.g., every few hundreds of milliseconds) or less rapidly (e.g., every 10 seconds).

In the exemplified embodiment, the control circuit 250 includes a processor. The processor may be any type of properly programmed processing device, such as a computer or microprocessor, configured for executing computer program instructions (e.g., code). The processor may be embodied in computer and/or server hardware of any suitable type (e.g., desktop, laptop, notebook, tablets, cellular phones, etc.) and may include all the usual ancillary components necessary to form a functional data processing device including without limitation a bus, software and data storage (such as volatile and non-volatile memory), input/output devices, graphical user interfaces (GUIs), removable data storage, and wired and/or wireless communication interface devices including Wi-Fi, Bluetooth, LAN, etc. The processor of the exemplified embodiment is configured with specific algorithms to enable the ICP source 200 to perform the functions described herein.

It is noted that the inductive coil circuit 210 may further comprise capacitors 241 and 242 coupled to the RF power source 204. In the exemplified embodiment, capacitor 241 is a first fixed capacitor coupled between a first output terminal (−V) of the RF power source 204 and one end of the first inductive coil circuit 210, and capacitor 242 is a second fixed capacitor coupled between a second output terminal (+V) of the of the RF power source 204 and an opposite end of the first inductive coil circuit 210. In other embodiments, however, these capacitors may be omitted.

In the exemplified embodiment of FIGS. 2-3, each intervening capacitor 221-223 comprises a single fixed capacitor. Further, each single fixed capacitor 221-223 is coupled to a corresponding one of the switches 231-233, the corresponding switch configured to short circuit the single fixed capacitor to switch the single fixed capacitor out of the inductive coil circuit. For example, switch 231 is configured to short circuit fixed capacitor 221.

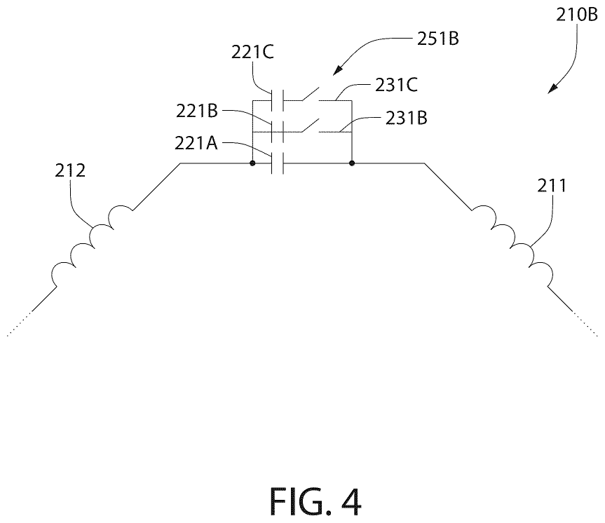

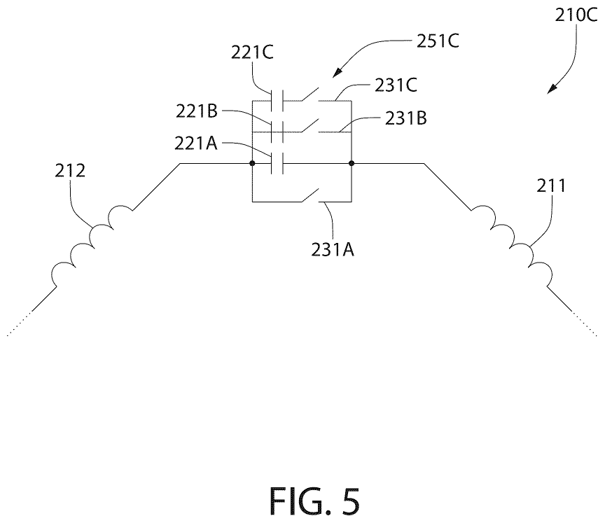

In other embodiments, one or more of the intervening capacitors may comprise a plurality of fixed capacitors coupled in parallel, as is shown, for example, in FIGS. 4 and 5. FIG. 4 is a schematic diagram of a portion of a second inductive coil circuit 210B according to a second embodiment. In this embodiment, the first capacitor switching circuit 251 of FIG. 3 is replaced by second capacitor switching circuit 251B. This switching circuit 251B includes three capacitors 221A, 221B, 221C coupled in parallel. Of those capacitors, capacitor 221A remains in the inductive coil circuit 210B at all times, including during ignition. The other two capacitors 221B, 221C may be switched out of the inductive coil circuit 210B by switches 231B, 231C, respectively, during ignition. In this approach, capacitor 221A may continuously provide a voltage decrease for reducing voltage in the inductive coils 211-214 and reduce over-heating of the dielectric tube 206, while switching capacitors 221B, 221C may switch out to aid ignition.

FIG. 5 provides a third inductive coil circuit 210C utilizing a third capacitor switching circuit 251C. The difference with the prior switching circuit 251B is that switching circuit 251C includes switch 231A, which is positioned to short circuit capacitor 221A. In this arrangement, all three capacitors 221A-C are capable of being switched out of the inductive coil circuit 210C. Thus, the circuit 210C is capable of providing a more significant reduction in voltage to aid in ignition.

It is noted that the invention is not limited to any particular number of capacitors coupled in parallel, or to any number of those capacitors being capable of being switched, or to any particular method of switching capacitors out of an inductive coil circuit. Further, adjacent inductors may use different capacitor switching circuits with different numbers of capacitors and different switching arrangements. Accordingly, in some cases, certain intervening capacitors (e.g., intervening capacitor 221) between adjacent inductive coils (e.g., coils 211, 212) may be switched out entirely during ignition, while other intervening capacitors (e.g., intervening capacitor 222) may remain switched in during ignition. The number of intervening caps to switch out may depend on how much ignition support is needed, which includes considerations such as how much voltage is needed in the inductive coil and the size and number of inductors.

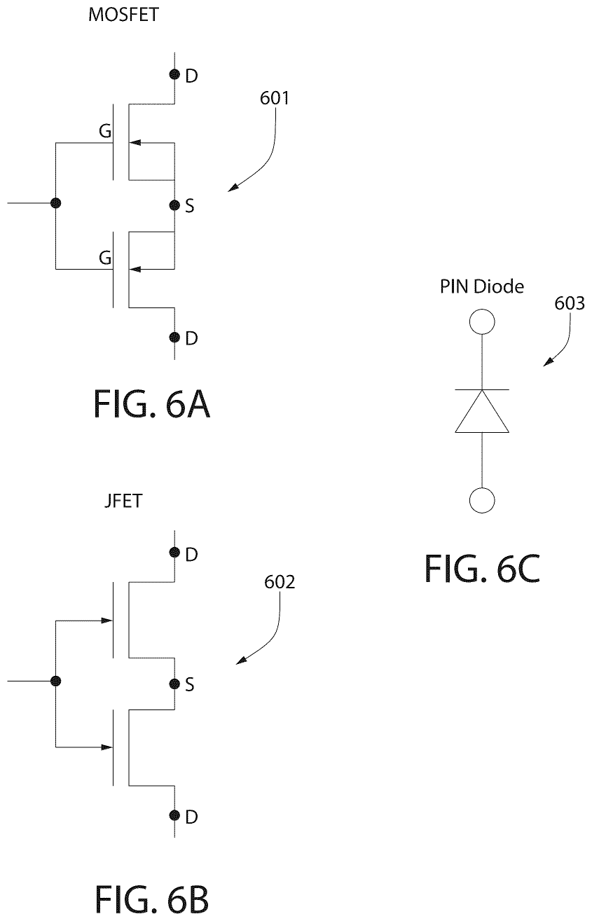

The invention is not limited to any particular type of switch to be used for switching in and out the intervening capacitors or the fixed capacitors that comprise the intervening capacitors. For example, the invention may use PIN diodes, NIP diodes, or FETs. FIGS. 6A-C provide schematic diagrams of example switches 601, 602, 603 that may be utilized. FIG. 6A shows a MOSFET switch, FIG. 6B shows a JFET switch, and FIG. 6C shows a PIN diode switch. The inductive coil circuit may use the same types of switches throughout or different types of switches.

It is noted that, for the sake of clarity and efficiency, the more common characteristics of an ICP source are not discussed in detail herein. For more details about potential characteristics of an ICP source, see, for example, U.S. Pat. No. 10,541,114 (incorporated by reference above) and its different ICP generation systems.

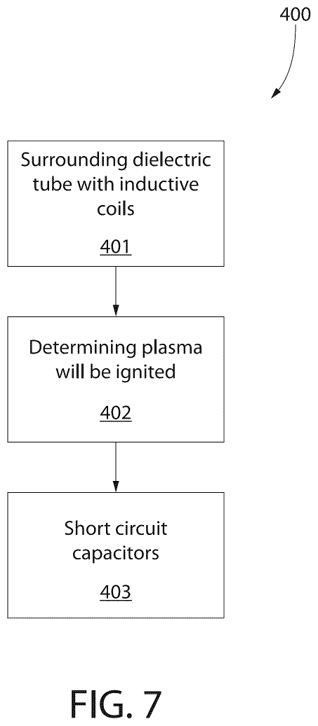

FIG. 7 is a flow chart of a method 400 for improving ignition of a plasma according to one embodiment. In a first operation 401, the dielectric tube 206 may be surrounded with inductive coils 211-214, as shown, for example, in FIG. 2. The inductive coils 211-214 form part of an inductive coil circuit, such as inductive coil circuits 210, 210B, and 210C discussed above. In a second operation 402, a determination is made that the plasma will be ignited as discussed above. In operation 403, upon determining a plasma 209 will be ignited, at least one of the switches 231-233 is caused to switch at least one of the fixed capacitors 221-223 of the intervening capacitors out of the inductive coil circuit 210 during ignition of the plasma 209. It is noted that the method 400 is not limited to the embodiments discussed above.

While the inventions have been described with respect to specific examples including presently preferred modes of carrying out the inventions, those skilled in the art will appreciate that there are numerous variations and permutations of the above described systems and techniques. It is to be understood that other embodiments may be utilized and structural and functional modifications may be made without departing from the scope of the present inventions. Thus, the spirit and scope of the inventions should be construed broadly as set forth in the appended claims.

What is claimed is:

1. A system comprising:
a dielectric tube;
an inductive coil circuit comprising:
inductive coils surrounding the dielectric tube and connected in series to each other;
intervening capacitors coupled between the inductive coils, each intervening capacitor comprising either one fixed capacitor or a plurality of fixed capacitors coupled in parallel; and
switches operably coupled to the intervening capacitors; and
a control circuit configured to, upon determining a plasma will be ignited, cause at least one of the switches to switch at least one of the fixed capacitors of the intervening capacitors out of the inductive coil circuit during ignition of the plasma.

2. The system of claim 1 wherein the control circuit is further configured to, after ignition of the plasma, cause the at least one of the fixed capacitors that was switched out of the inductive coil circuit to be switched back into the inductive coil circuit.

3. The system of claim 1 wherein each intervening capacitor is respectively coupled between adjacent ones of the inductive coils.

4. The system of claim 1 wherein each intervening capacitor is a single fixed capacitor.

5. The system of claim 4 wherein each single fixed capacitor is coupled to a corresponding one of the switches, the corresponding switch configured to short circuit the single fixed capacitor to switch the single fixed capacitor out of the inductive coil circuit.

6. The system of claim 1 wherein at least one of the intervening capacitors comprises a plurality of fixed capacitors coupled in parallel, and wherein, during ignition of the plasma, a portion of the plurality of fixed capacitors is switched out of the inductive coil circuit and a portion of the plurality of fixed capacitors is not switched out of the inductive coil circuit.

7. The system of claim 1 wherein the inductive coil circuit is configured to produce inductively-coupled plasma.

8. The system of claim 1 wherein the intervening capacitors are in series with the inductive coils, and wherein the switches comprise PIN diodes, NIP diodes, or FETs.

9. The system of claim 1 wherein the determination the plasma will be ignited comprises a determination that RF power being provided by an RF power source to the inductive coil circuit has turned OFF.

10. The system of claim 1:
further comprising an RF power source providing RF power to the inductive coil circuit;
wherein, upon determining a plasma will be ignited, the control circuit is further configured to decrease a frequency of the RF power provided by the RF power source.

11. A method of improving ignition of plasma, the method comprising:
surrounding a dielectric tube with inductive coils of an inductive coil circuit, the inductive coil circuit comprising:
the inductive coils connected in series to each other;
intervening capacitors coupled between the inductive coils, each intervening capacitor comprising one or more fixed capacitors coupled in parallel; and
switches operably coupled to the intervening capacitors; and
upon determining a plasma will be ignited, causing at least one of the switches to switch at least one of the fixed capacitors of the intervening capacitors out of the inductive coil circuit during ignition of the plasma.

12. The method of claim 11 further comprising, after ignition of the plasma, causing the at least one of the fixed capacitors that was switched out of the inductive coil circuit to be switched back into the inductive coil circuit.

13. The method of claim 11 wherein each intervening capacitor is respectively coupled between adjacent ones of the inductive coils.

14. The method of claim 11 wherein each intervening capacitor is a single fixed capacitor.

15. The method of claim 14 wherein each single fixed capacitor is coupled to a corresponding one of the switches, the corresponding switch configured to short circuit the single fixed capacitor to switch the single fixed capacitor out of the inductive coil circuit.

16. The method of claim 11 wherein at least one of the intervening capacitors comprises a plurality of fixed capacitors coupled in parallel, and wherein, during ignition of the plasma, a portion of the plurality of fixed capacitors is switched out of the inductive coil circuit and a portion of the plurality of fixed capacitors is not switched out of the inductive coil circuit.

17. The method of claim 11 wherein the inductive coil circuit is configured to produce inductively-coupled plasma.

18. The method of claim 11 wherein the intervening capacitors are in series with the inductive coils, and wherein the switches comprise PIN diodes, NIP diodes, or FETs.

19. The method of claim 11 wherein the determination the plasma will be ignited comprises a determination that RF power being provided by an RF power source to the inductive coil circuit has turned OFF.

20. The method of claim 11:
further comprising an RF power source providing RF power to the inductive coil circuit; and
upon determining a plasma will be ignited, decreasing a frequency of the RF power provided by the RF power source.
